(19) United States
(12) Patent Application Publication
(10) Pub. No.: US 2015/0237720 A1
(43) Pub. Date: Aug. 20, 2015

(54) WATERMARKED CONDUCTIVE PATTERN

(71) Applicant: Uni-Pixel Displays, Inc., The Woodlands, TX (US)

(72) Inventor: Daniel Van Ostrand, Conroe, TX (US)

(73) Assignee: Uni-Pixel Displays, Inc., The Woodlands, TX (US)

(21) Appl. No.: 14/182,164

(22) Filed: Feb. 17, 2014

(51) Int. Cl. H05K 1/02; H05K 1/09

(52) U.S. Cl. CPC H05K 1/0296; H05K 1/09; H05K 2201/10128; H05K 2201/09227; H05K 2201/0326; H05K 2201/0344; H05K 2201/2054

(57) ABSTRACT

A watermarked conductive pattern includes a conductive pattern disposed on a transparent substrate, a plurality of watermark filler shapes disposed on the transparent substrate in a predetermined watermark area, and a plurality of background filler shapes disposed on the transparent substrate in an area adjacent to the predetermined watermark area.

### BACKGROUND OF THE INVENTION

A touch screen enabled system allows a user to control various aspects of the system by touch or gestures. For example, a user may interact directly with objects depicted on a display device by touch or gestures that are sensed by a touch sensor. The touch sensor typically includes a pattern of conductive lines disposed on a substrate configured to sense touch.

Touch screens are commonly found in consumer systems, commercial systems, and industrial systems including, but not limited to, smartphones, tablet computers, laptop computers, desktop computers, printers, monitors, televisions, appliances, kiosks, copiers, desktop phones, automotive display systems, portable gaming devices, and gaming consoles.

### BRIEF SUMMARY OF THE INVENTION

According to one aspect of one or more embodiments of the present invention, a watermarked conductive pattern includes a conductive pattern disposed on a transparent substrate, a plurality of watermark filler shapes disposed on the transparent substrate in a predetermined watermark area, and a plurality of background filler shapes disposed on the transparent substrate in an area adjacent to the predetermined watermark area.

According to one aspect of one or more embodiments of the present invention, a watermarked display device includes a display device and a transparent substrate. A plurality of watermark filler shapes are disposed on the transparent substrate in a predetermined watermark area. A plurality of background filler shapes are disposed on the transparent substrate in an area adjacent to the predetermined watermark area.

Other aspects of the present invention will be apparent from the following description and claims.

### BRIEF DESCRIPTION OF THE DRAWINGS

FIG. 1 shows a cross section of a touch screen in accordance with one or more embodiments of the present invention.

FIG. 2 shows a schematic view of a touch screen enabled computing system in accordance with one or more embodiments of the present invention.

FIG. 3 shows a functional representation of a touch sensor as part of a touch screen in accordance with one or more embodiments of the present invention.

FIG. 4A shows a cross-section of a touch sensor with conductive patterns disposed on opposing sides of a transparent substrate in accordance with one or more embodiments of the present invention.

FIG. 4B shows a cross-section of a touch sensor with a first conductive pattern disposed on a first transparent substrate and a second conductive pattern disposed on a second transparent substrate in accordance with one or more embodiments of the present invention.

FIG. 4C shows a cross-section of a touch sensor with a first conductive pattern disposed on a first transparent substrate and a second conductive pattern disposed on a second transparent substrate in accordance with one or more embodiments of the present invention.

FIG. 4D shows a cross-section of a touch sensor with a first conductive pattern disposed on a first transparent substrate and a second conductive pattern disposed on a second transparent substrate in accordance with one or more embodiments of the present invention.

FIG. 4E shows a cross-section of a touch sensor with a first conductive pattern disposed on a first transparent substrate and a second conductive pattern disposed on a second transparent substrate in accordance with one or more embodiments of the present invention.

FIG. 4F shows a cross-section of a touch sensor with a first conductive pattern disposed on a transparent substrate in accordance with one or more embodiments of the present invention.

FIG. 4G shows a cross-section of a touch sensor with a first conductive pattern disposed on a transparent substrate in accordance with one or more embodiments of the present invention.

FIG. 4H shows a cross-section of a touch sensor with a first conductive pattern disposed on a cover lens in accordance with one or more embodiments of the present invention.

FIG. 5 shows a first conductive pattern disposed on a transparent substrate in accordance with one or more embodiments of the present invention.

FIG. 6 shows a second conductive pattern disposed on a transparent substrate in accordance with one or more embodiments of the present invention.

FIG. 7 shows a portion of a touch sensor in accordance with one or more embodiments of the present invention.

FIG. 8A shows a portion of a watermarked conductive pattern in accordance with one or more embodiments of the present invention.

FIG. 8B shows a zoomed in view of a portion of the watermarked conductive pattern in accordance with one or more embodiments of the present invention.

FIG. 9A shows a rectangular filler shape in accordance with one or more embodiments of the present invention.

FIG. 9B shows a circular filler shape in accordance with one or more embodiments of the present invention.

FIG. 9C shows an oval filler shape in accordance with one or more embodiments of the present invention.

FIG. 9D shows a square filler shape in accordance with one or more embodiments of the present invention.

FIG. 10A shows a left perspective view of a tablet with a watermarked conductive pattern or watermarked display device in accordance with one or more embodiments of the present invention.

FIG. 10B shows a user-facing perspective view of the tablet with the watermarked conductive pattern or watermarked display device in accordance with one or more embodiments of the present invention.

FIG. 10C shows a right perspective view of the tablet with the watermarked conductive pattern or watermarked display device in accordance with one or more embodiments of the present invention.

FIG. 11A shows a left perspective view of a smartphone with a watermarked conductive pattern or watermarked display device in accordance with one or more embodiments of the present invention.

FIG. 11B shows a user-facing perspective view of the smartphone with the watermarked conductive pattern or watermarked display device in accordance with one or more embodiments of the present invention.

FIG. 11C shows a right perspective view of the smartphone with the watermarked conductive pattern or watermarked display device in accordance with one or more embodiments of the present invention.

FIG. 12A shows a left perspective view of a laptop with a watermarked conductive pattern or watermarked display device in accordance with one or more embodiments of the present invention.

FIG. 12B shows a user-facing perspective view of the laptop with the watermarked conductive pattern or watermarked display device in accordance with one or more embodiments of the present invention.

FIG. 12C shows a right perspective view of the laptop with the watermarked conductive pattern or watermarked display device in accordance with one or more embodiments of the present invention.

FIG. 13A shows a left perspective view of a monitor with a watermarked conductive pattern or watermarked display device in accordance with one or more embodiments of the present invention.

FIG. 13B shows a user-facing perspective view of the monitor with the watermarked conductive pattern or watermarked display device in accordance with one or more embodiments of the present invention.

FIG. 13C shows a right perspective view of the monitor with the watermarked conductive pattern or watermarked display device in accordance with one or more embodiments of the present invention.

### DETAILED DESCRIPTION OF THE INVENTION

One or more embodiments of the present invention are described in detail with reference to the accompanying figures. For consistency, like elements in the various figures are denoted by like reference numerals. In the following detailed description of the present invention, specific details are set forth in order to provide a thorough understanding of the present invention. In other instances, well-known features to one of ordinary skill in the art are not described to avoid obscuring the description of the present invention.

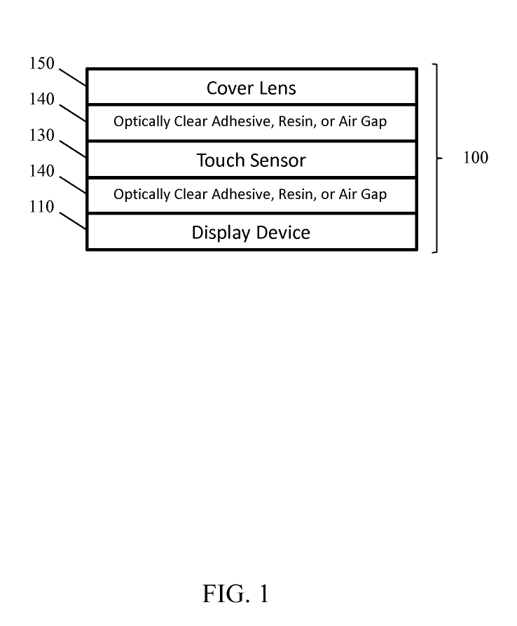

FIG. 1 shows a cross-section of a touch screen 100 in accordance with one or more embodiments of the present invention. Touch screen 100 includes a display device 110. Display device 110 may be a Liquid Crystal Display (“LCD”), Light-Emitting Diode (“LED”), Organic Light-Emitting Diode (“OLED”), Active Matrix Organic Light-Emitting Diode (“AMOLED”), In-Plane Switching (“IPS”), or other type of display device suitable for use as part of a touch screen application or design. In one or more embodiments of the present invention, a touch sensor 130 may overlay display device 110. In certain embodiments, an optically clear adhesive or resin 140 may bond a bottom side of touch sensor 130 to a top, or user-facing, side of display device 110. In other embodiments, an isolation layer, or air gap, 140 may separate the bottom side of touch sensor 130 from the top, or user-facing, side of display device 110. A cover lens 150 may overlay touch sensor 130. Cover lens 150 may be composed of glass, plastic, film, or other material. In certain embodiments, an optically clear adhesive or resin 140 may bond a bottom side of cover lens 150 to a top, or user-facing, side of touch sensor 130. In other embodiments, an isolation layer, or air gap, 140 may separate the bottom side of cover lens 150 and the top, or user-facing, side of touch sensor 130. A top side of cover lens 150 faces the user and protects the underlying components of touch screen 100. One of ordinary skill in the art will recognize that other embodiments, including those where a touch sensor is integrated into the display device 110 stack, may be used in accordance with one or more embodiments of the present invention. One of ordinary skill in the art will also recognize that touch sensor 130 may be a capacitive, resistive, optical, or acoustic touch sensor. One of ordinary skill in the art will recognize that touch sensor 130 may include, for example, a flexographically printed conductive pattern, a flexographically printed seed pattern metallized to form a conductive pattern, an indium tin oxide (“ITO”) conductive pattern, or other transparent or opaque conductive pattern in accordance with one or more embodiments of the present invention. One of ordinary skill in the art will also recognize that touch sensor 130 may include other components of touch screen 100, such as, for example, the optically clear adhesive, resin, or air gap layer 140 and/or cover lens 150, as part of touch sensor 130 stackup.

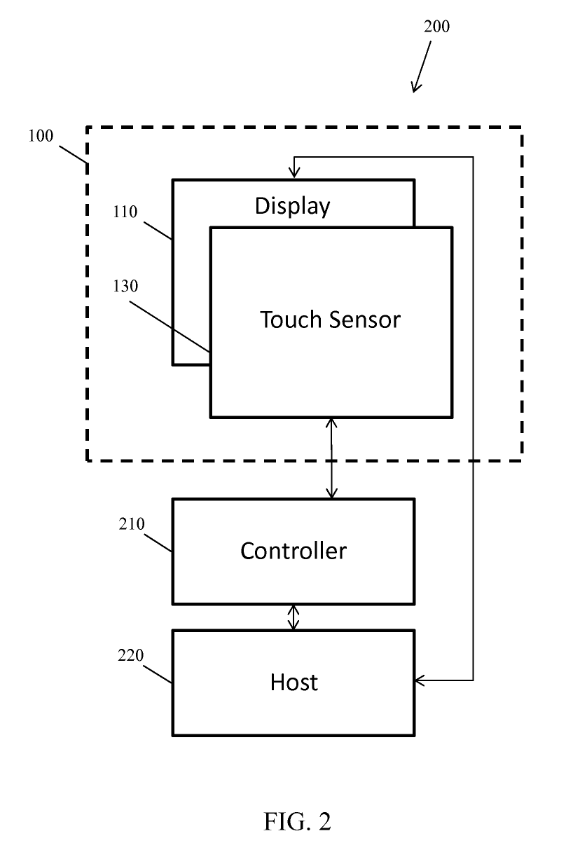

FIG. 2 shows a schematic view of a touch screen enabled computing system 200 in accordance with one or more embodiments of the present invention. Computing system 200 may be a consumer computing system, commercial computing system, or industrial computing system including, but not limited to, smartphones, tablet computers, laptop computers, desktop computers, printers, monitors, televisions, appliances, kiosks, automatic teller machines, copiers, desktop phones, automotive display systems, portable gaming devices, gaming consoles, or other applications or designs suitable for use with touch screen 100.

Computing system 200 may include one or more printed or flex circuits (not shown) on which one or more processors (not shown) and system memory (not shown) may be disposed. Each of the one or more processors may be a single-core processor (not shown) or a multi-core processor (not shown) capable of executing software instructions. Multi-core processors typically include a plurality of processor cores disposed on the same physical die (not shown) or a plurality of processor cores disposed on multiple die (not shown) disposed within the same mechanical package (not shown). Computing system 200 may include one or more input/output devices (not shown), one or more local storage devices (not shown) including solid-state memory, a fixed disk drive, a fixed disk drive array, or any other non-transitory computer readable medium, a network interface device (not shown), and/or one or more network storage devices (not shown) including network-attached storage devices and cloud-based storage devices.

In certain embodiments, touch screen 100 may include display device 110 and touch sensor 130 that overlays at least a portion of a viewable area of display device 110. In other embodiments, touch sensor 130 may be integrated into display device 110. Controller 210 electrically drives at least a portion of touch sensor 130. Touch sensor 130 senses touch (capacitance, resistance, optical, or acoustic) and conveys information corresponding to the sensed touch to controller 210. In typical applications, the manner in which the sensing of touch is measured, tuned, and/or filtered may be configured by controller 210. In addition, controller 210 may recognize one or more gestures based on the sensed touch or touches. Controller 210 provides host 220 with touch or gesture information corresponding to the sensed touch or touches. Host 220 may use this touch or gesture information as user input and respond in an appropriate manner. In this way, the user may interact with computing system 200 by touch or gestures on touch screen 100. In certain embodiments, host 220 may be the one or more printed or flex circuits (not shown) on which the one or more processors (not shown) are disposed. In other embodiments, host 220 may be a subsystem or any other part of computing system 200 that is configured to interface with display device 110 and controller 210.

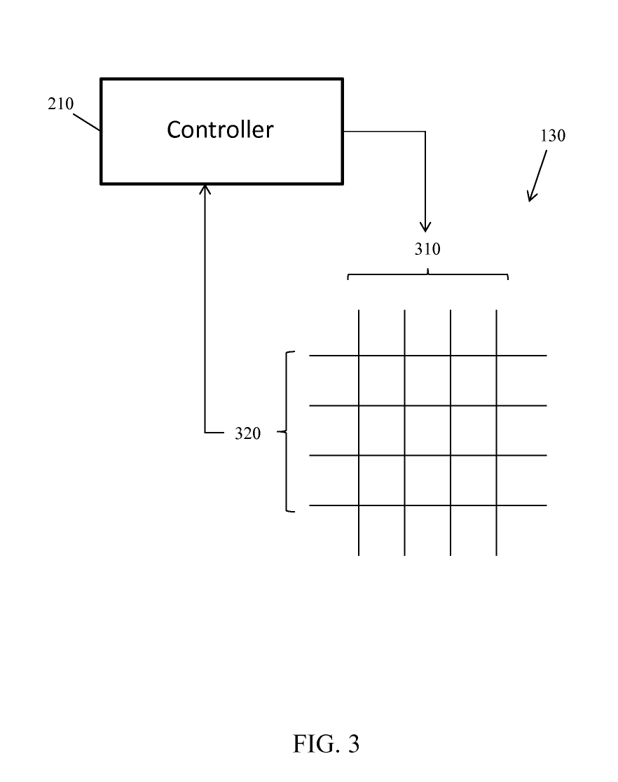

FIG. 3 shows a functional representation of a touch sensor 130 as part of a touch screen 100 in accordance with one or more embodiments of the present invention. In certain embodiments, touch sensor 130 may be viewed as a plurality of column lines 310 and a plurality of row lines 320 arranged as a mesh grid. The number of column lines 310 and the number of row lines 320 may not be the same and may vary based on an application or a design. The apparent intersections of column lines 310 and row lines 320 may be viewed as uniquely addressable locations of touch sensor 130. In operation, controller 210 may electrically drive one or more row lines 320 and touch sensor 130 may sense touch on one or more column lines 310 that are sampled by controller 210. One of ordinary skill in the art will recognize that the role of column lines 310 and row lines 320 may be reversed such that controller 210 electrically drives one or more column lines 310 and touch sensor 130 senses touch on one or more row lines 320 that are sampled by controller 210.

In certain embodiments, controller 210 may interface with touch sensor 130 by a scanning process. In such an embodiment, controller 210 may electrically drive a selected row line 320 (or column line 310) and sample all column lines 310 (or row lines 320) that intersect the selected row line 320 (or the selected column line 310) by measuring, for example, capacitance at each intersection. This process may be continued through all row lines 320 (or all column lines 310) such that capacitance is measured at each uniquely addressable location of touch sensor 130 at a predetermined interval. Controller 210 may allow for the adjustment of the scan rate depending on the needs of a particular design or application. One of ordinary skill in the art will recognize that the scanning process discussed above may also be used with other touch sensor technologies, applications, or designs in accordance with one or more embodiments of the present invention.

In other embodiments, controller 210 may interface with touch sensor 130 by an interrupt driven process. In such an embodiment, a touch or a gesture generates an interrupt to controller 210 that triggers controller 210 to read one or more of its own registers that store sensed touch information sampled from touch sensor 130 at predetermined intervals. One of ordinary skill in the art will recognize that the mechanism by which touch or gestures are sensed by touch sensor 130 and sampled by controller 210 may vary based on an application or a design in accordance with one or more embodiments of the present invention.

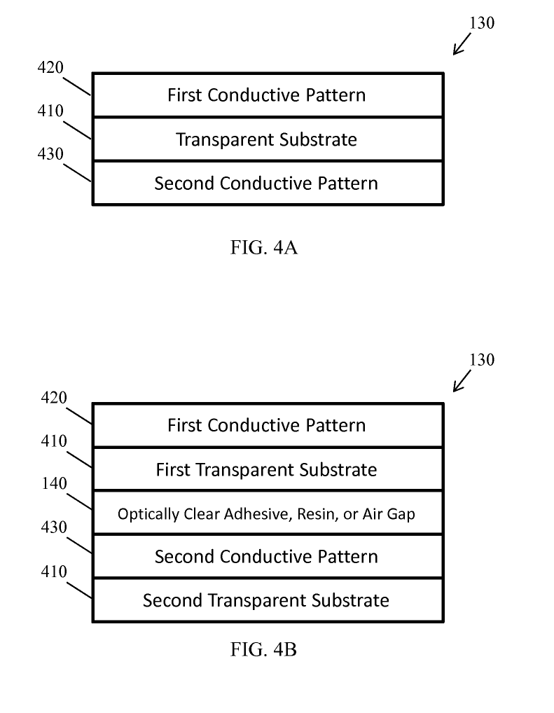

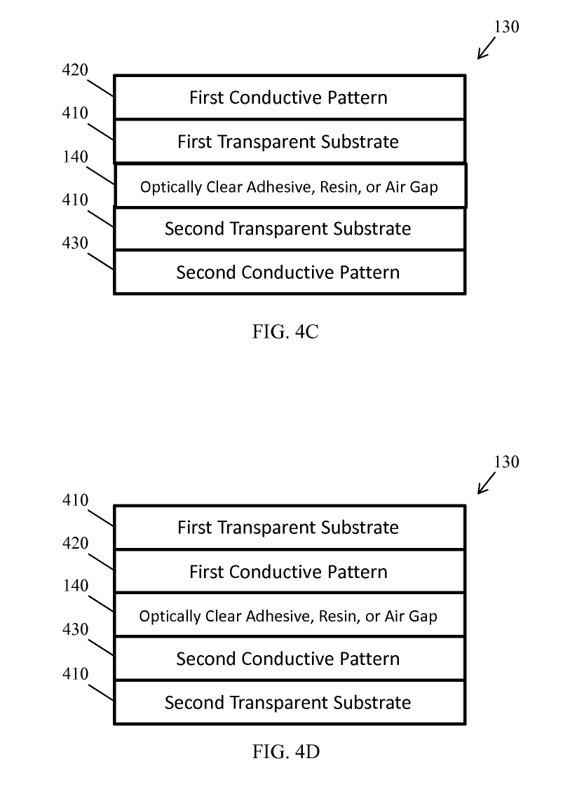

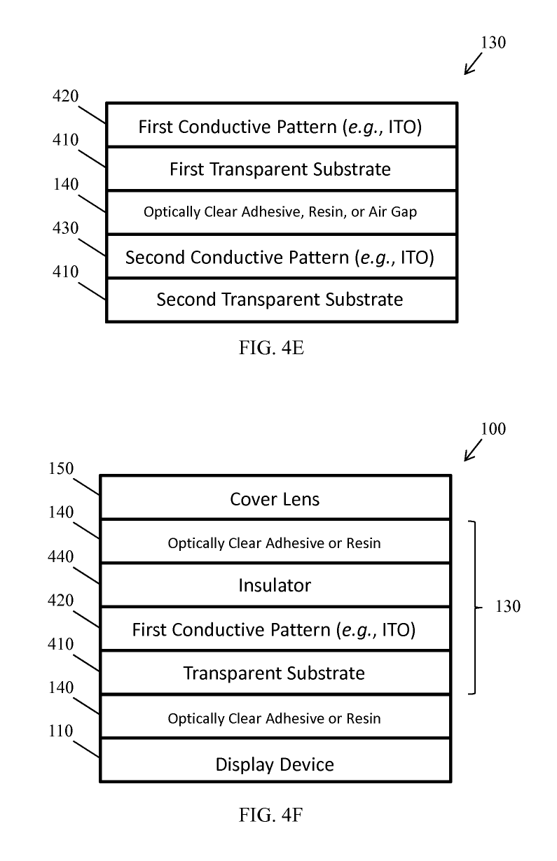

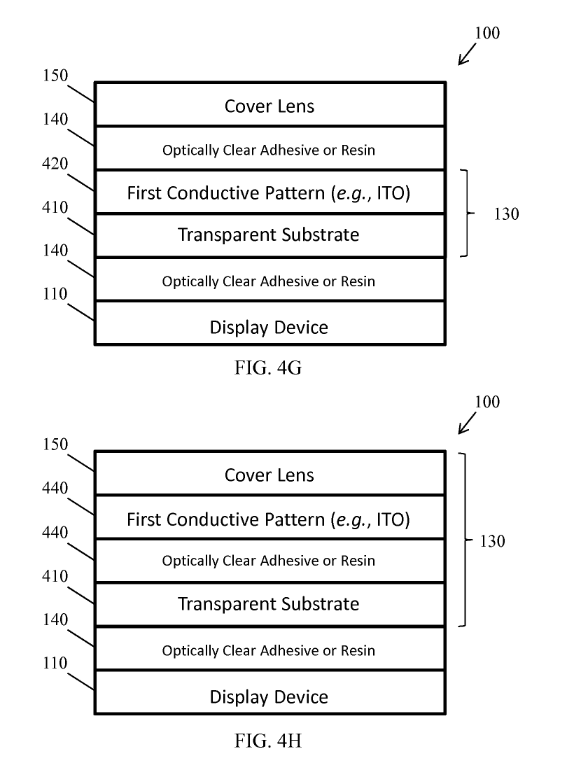

FIG. 4A shows a cross-section of a touch sensor 130 with conductive patterns 420 and 430 disposed on opposing sides of a transparent substrate 410 in accordance with one or more embodiments of the present invention. In certain embodiments, touch sensor 130 may include a first conductive pattern 420 disposed on a top, or user-facing, side of a transparent substrate 410 and a second conductive pattern 430 disposed on a bottom side of the transparent substrate 410. One of ordinary skill in the art will recognize that a conductive pattern may be any shape or pattern of one or more conductors in accordance with one or more embodiments of the present invention.

FIG. 4B shows a cross-section of a touch sensor 130 with a first conductive pattern 420 disposed on a first transparent substrate 410 and a second conductive pattern 430 disposed on a second transparent substrate 410 in accordance with one or more embodiments of the present invention. In certain embodiments, touch sensor 130 may include first conductive pattern 420 disposed on a top, or user-facing, side of the first transparent substrate 410 and second conductive pattern 430 disposed on a top side of the second transparent substrate 410. A bottom side of the first transparent substrate 410 may overlay the second conductive pattern 430 disposed on the top side of the second transparent substrate 410 at a predetermined alignment. In certain embodiments, the first transparent substrate 410 may be bonded to the second transparent substrate 410 by a lamination process (not shown). In other embodiments, the first transparent substrate 410 may be bonded to the second transparent substrate 410 by an optically clear adhesive or resin 140. In still other embodiments, the first transparent substrate 410 and the second transparent substrate 410 may be secured in place and there may be an isolation layer, or air gap, 140 disposed between the bottom side of the first transparent substrate 410 and the second conductive pattern 430 disposed on the top side of the second transparent substrate 410.

FIG. 4C shows a cross-section of a touch sensor 130 with a first conductive pattern 420 disposed on a first transparent substrate 410 and a second conductive pattern 430 disposed on a second transparent substrate 410 in accordance with one or more embodiments of the present invention. In certain embodiments, touch sensor 130 may include first conductive pattern 420 disposed on a top, or user-facing, side of first transparent substrate 410 and second conductive pattern 430 disposed on a bottom side of second transparent substrate 410. A bottom side of the first transparent substrate 410 may overlay a top side of the second transparent substrate 410 at a predetermined alignment. In certain embodiments, the first transparent substrate 410 may be bonded to the second transparent substrate 410 by a lamination process (not shown). In other embodiments, the first transparent substrate 410 may be bonded to the second transparent substrate 410 by an optically clear adhesive or resin 140. In still other embodiments, the first transparent substrate 410 and the second transparent substrate 410 may be secured in place and there may be an isolation layer, or air gap, 140 disposed between the bottom side of the first transparent substrate 410 and the top side of the second transparent substrate 410.

FIG. 4D shows a cross-section of a touch sensor 130 with a first conductive pattern 420 disposed on a first transparent substrate 410 and a second conductive pattern 430 disposed on a second transparent substrate 410 in accordance with one or more embodiments of the present invention. In certain embodiments, touch sensor 130 may include first conductive pattern 420 disposed on a bottom side of the first transparent substrate 410 and second conductive pattern 430 disposed on a top side of the second transparent substrate 410. The first conductive pattern 420 disposed on the bottom side of the first transparent substrate 410 may overlay the second conductive pattern 430 disposed on the top side of the second transparent substrate 410 at a predetermined alignment. In certain embodiments, the first transparent substrate 410 may be bonded to the second transparent substrate 410 by a lamination process (not shown). In other embodiments, the first transparent substrate 410 may be bonded to the second transparent substrate 410 by an optically clear adhesive or resin 140. In still other embodiments, the first transparent substrate 410 and the second transparent substrate 410 may be secured in place and there may be an isolation layer, or air gap, 140 disposed between the first conductive pattern 420 disposed on the bottom side of the first transparent substrate 410 and the second conductive pattern 430 disposed on the top side of the second transparent substrate 410.

FIG. 4E shows a cross-section of a touch sensor 130 with a first conductive pattern 420 disposed on a first transparent substrate 410 and a second conductive pattern 430 disposed on a second transparent substrate 410 in accordance with one or more embodiments of the present invention. In certain ITO applications, first conductive pattern 420 and second conductive pattern 430 may comprise ITO conductors. First conductive pattern 420 may be disposed on a top, or user-facing, side of the first transparent substrate 410 and second conductive pattern 430 may be disposed on a top side of the second transparent substrate 410. A bottom side of the first transparent substrate 410 may overlay the second conductive pattern 430 disposed on the top side of the second transparent substrate 410 at a predetermined alignment. In certain embodiments, the first transparent substrate 410 may be bonded to the second transparent substrate 410 by a lamination process (not shown). In other embodiments, the first transparent substrate 410 may be bonded to the second transparent substrate 410 by an optically clear adhesive or resin 140. In still other embodiments, the first transparent substrate 410 and the second transparent substrate 410 may be secured in place and there may be an isolation layer, or air gap, 140 disposed between the bottom side of the first transparent substrate 410 and the second conductive pattern 430 disposed on the top side of the second transparent substrate 410. One of ordinary skill in the art will recognize that other dual layer ITO stackups may be used in accordance with one or more embodiments of the present invention.

FIG. 4F shows a cross-section of a touch sensor 130 with a first conductive pattern 420 disposed on a transparent substrate 410 in accordance with one or more embodiments of the present invention. In certain ITO applications, first conductive pattern 420 may comprise ITO conductors. First conductive pattern 420 may be disposed on a top, or user-facing, side of a transparent substrate 410. Portions of the first conductive pattern 420 may extend through an insulator layer 440 and extend into an optically clear adhesive or resin layer 140. Insulator layer 440 may be comprised of a portion of the optically clear adhesive or resin layer 140. The portion of first conductive pattern 420 that extends into the optically clear adhesive or resin layer 140 may function as a second conductive pattern (not shown) for purposes of touch sensor operation. One of ordinary skill in the art will recognize that other “1.5” layer ITO stackups may be used in accordance with one or more embodiments of the present invention.

FIG. 4G shows a cross-section of a touch sensor 130 with a first conductive pattern 420 disposed on a transparent substrate 410 in accordance with one or more embodiments of the present invention. In certain ITO applications, first conductive pattern 420 may comprise ITO conductors. First conductive pattern 420 may be disposed on a top, or user-facing, side of a transparent substrate 410. First conductive pattern 420 may comprise a pattern that is functionally equivalent to a combination of a first conductive pattern and a second conductive pattern (not shown) that fits in a single layer. One of ordinary skill in the art will recognize that other single layer ITO stackups may be used in accordance with one or more embodiments of the present invention. In other embodiments, first conductive pattern 420 may be used to watermark a discrete display device that may or may not provide touch sensor functionality.

FIG. 4H shows a cross-section of a touch sensor 130 with a first conductive pattern 420 disposed on a cover lens 150 in accordance with one or more embodiments of the present invention. In certain ITO applications, first conductive pattern 420 may comprise ITO conductors. First conductive pattern 420 may be disposed on a bottom side of a cover lens 150. First conductive pattern 420 may comprise a pattern that is functionally equivalent to a combination of a first conductive pattern and a second conductive pattern (not shown) that fits in a single layer. One of ordinary skill in the art will recognize that other On-Glass Solution (“OGS”) ITO stackups may be used in accordance with one or more embodiments of the present invention. In other embodiments, first conductive pattern 420 may be used to watermark a discrete display device that may or may not provide touch sensor functionality.

With reference to FIGS. 4A through 4E, one of ordinary skill in the art will recognize that the disposition of the first conductive pattern and the second conductive pattern may be reversed in accordance with one or more embodiments of the present invention. One of ordinary skill in the art will also recognize that one or more of the embodiments depicted in FIGS. 4A through 4H could be used in applications where a touch sensor 130 or watermarked layer (not shown) is integrated into a display device (e.g., display device 110 of FIG. 1 or FIG. 2) in accordance with one or more embodiments of the present invention. As such, one of ordinary skill in the art will recognize that, in addition to the embodiments depicted in FIGS. 4A through 4H, other stackups, including those that vary in the number, type, or organization of substrate(s) and/or conductive pattern(s) are within the scope of one or more embodiments of the present invention. One of ordinary skill in the art will also recognize that a conductive pattern may be comprised of metal, metal alloys, metal nanowires, metal nanoparticle inks or coatings, metallic lines, metallic wires, transparent conductors including ITO, Poly(3,4-ethylenedioxythiophene) (“PEDOT”), or any other conductive material capable of being disposed on a transparent substrate in accordance with one or more embodiments of the present invention.

In certain embodiments, where one or more conductive patterns are used for watermarking only (i.e., no touch sensor functionality), one of ordinary skill in the art will recognize that any of the above-noted embodiments may be used with minor modification. In embodiments where only a single conductive pattern is necessary for watermarking, a second conductive pattern may not be used. One of ordinary skill in the art will recognize that the watermarking technique disclosed herein may be used for purely decorative effect without providing touch sensor functionality.

A conductive pattern (e.g., first conductive pattern 420 or second conductive pattern 430) may be disposed on one or more transparent substrates 410 by any process suitable for disposing conductive lines or features on a substrate. Suitable processes may include, for example, printing processes, vacuum-based deposition processes, solution coating processes, or cure/etch processes that either form conductive lines or features on substrate or form seed lines or features on substrate that may be further processed to form conductive lines or features on substrate. Printing processes may include flexographic printing, including the flexographic printing of a catalytic ink that may be metallized by an electroless plating process that plates a metal on top of the printed catalytic ink or direct flexographic printing of conductive ink or other materials capable of being flexographically printed, gravure printing, inkjet printing, rotary printing, or stamp printing. Deposition processes may include pattern-based deposition, chemical vapor deposition, electro deposition, epitaxy, physical vapor deposition, or casting. Cure/etch processes may include optical or UV-based photolithography, e-beam/ion-beam lithography, x-ray lithography, interference lithography, scanning probe lithography, imprint lithography, or magneto lithography. One of ordinary skill in the art will recognize that any process or combination of processes, suitable for disposing conductive lines or features on substrate, may be used in accordance with one or more embodiments of the present invention.

With respect to transparent substrate 410, transparent means the transmission of visible light with a transmittance rate of 85% or more. In certain embodiments, transparent substrate 410 may be polyethylene terephthalate (“PET”), polyethylene naphthalate (“PEN”), cellulose acetate (“TAC”), cycloaliphatic hydrocarbons (“COP”), bi-axially-oriented polypropylene (“BOPP”), polyester, polycarbonate, glass, or combinations thereof. In other embodiments, transparent substrate 410 may be any other transparent material suitable for use as a touch sensor or watermark substrate. One of ordinary skill in the art will recognize that the composition of transparent substrate 410 may vary based on an application or design in accordance with one or more embodiments of the present invention.

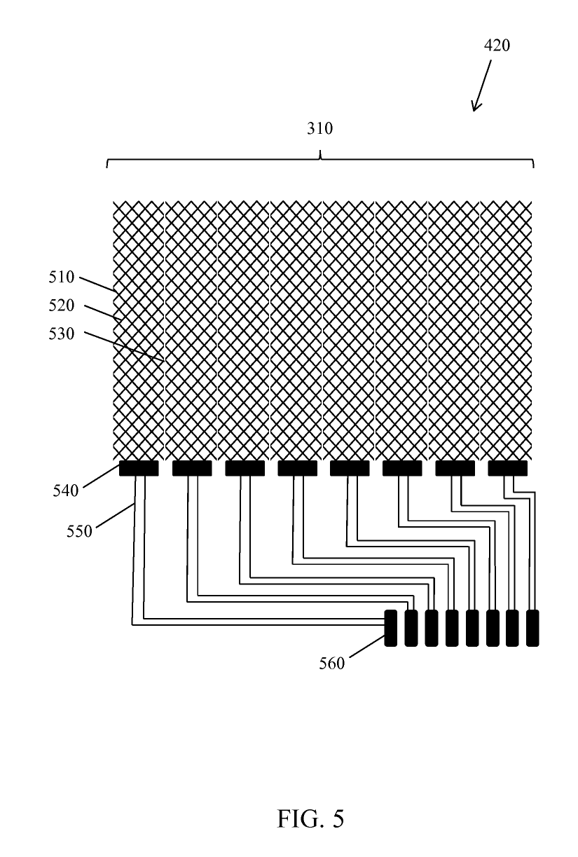

FIG. 5 shows a first conductive pattern 420 disposed on a transparent substrate (e.g., transparent substrate 410) in accordance with one or more embodiments of the present invention. In certain embodiments, first conductive pattern 420 may include a mesh formed by a plurality of parallel conductive lines oriented in a first direction 510 and a plurality of parallel conductive lines oriented in a second direction 520 that are disposed on a side of a transparent substrate (e.g., transparent substrate 410). One of ordinary skill in the art will also recognize that a size of first conductive pattern 420 may vary based on an application or a design in accordance with one or more embodiments of the present invention. In other embodiments (not independently illustrated), first conductive pattern 420 may include any other pattern formed by one or more conductive lines or features in any shape or pattern. One of ordinary skill in the art will recognize that the composition of a conductive pattern may vary based on an application or design in accordance with one or more embodiments of the present invention.

In certain embodiments, the plurality of parallel conductive lines oriented in the first direction 510 may be perpendicular to the plurality of parallel conductive lines oriented in the second direction 520, thereby forming the mesh. In other embodiments, the plurality of parallel conductive lines oriented in the first direction 510 may be angled relative to the plurality of parallel conductive lines oriented in the second direction 520, thereby forming the mesh. One of ordinary skill in the art will recognize that the relative angle between the plurality of parallel conductive lines oriented in the first direction 510 and the plurality of parallel conductive lines oriented in the second direction 520 may vary based on an application or a design in accordance with one or more embodiments of the present invention. In other embodiments (not independently illustrated), a conductive pattern may include one or more conductive lines or features in any shape or pattern. One of ordinary skill in the art will also recognize that a conductive pattern is not limited to sets of parallel conductive lines and could be any other shape or pattern, including predetermined or random orientations of line segments, curved line segments, conductive particles, polygons, or any other shape(s) or pattern(s) comprised of electrically conductive material in accordance with one or more embodiments of the present invention.

In certain embodiments, a plurality of breaks 530 may partition first conductive pattern 420 into a plurality of column lines 310, each electrically partitioned from the others. Each column line 310 may route to a channel pad 540. Each channel pad 540 may route to an interface connector 560 by way of one or more interconnect conductive lines 550. Interface connectors 560 may provide a connection interface between a touch sensor (130 of FIG. 1) and a controller (210 of FIG. 2).

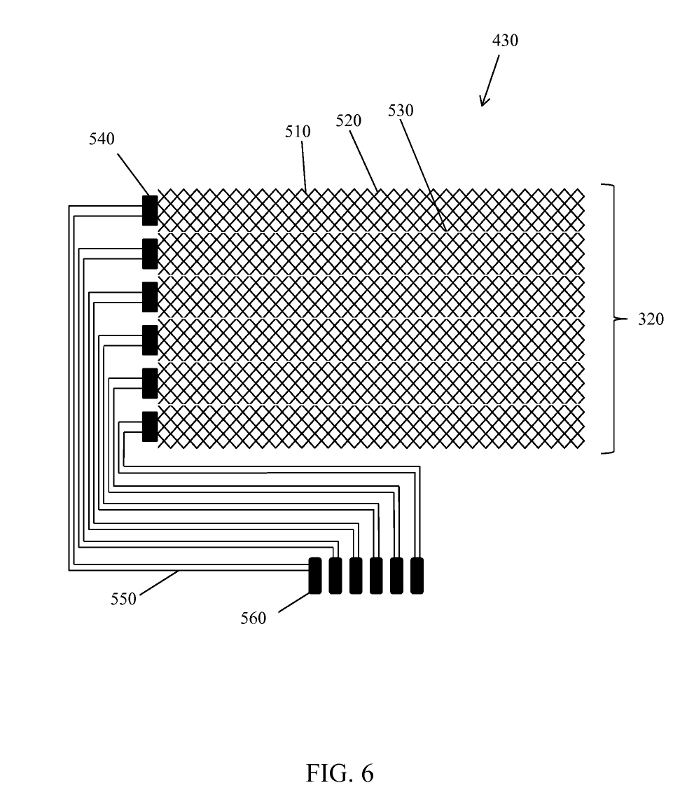

FIG. 6 shows a second conductive pattern 430 disposed on a second transparent substrate (e.g., transparent substrate 410) in accordance with one or more embodiments of the present invention. In certain embodiments, second conductive pattern 430 may include a mesh formed by a plurality of parallel conductive lines oriented in a first direction 510 and a plurality of parallel conductive lines oriented in a second direction 520 disposed on a side of a transparent substrate (e.g., transparent substrate 410). In certain embodiments, the second conductive pattern 430 may be substantially similar in size to the first conductive pattern 420. One of ordinary skill in the art will recognize that a size of the second conductive pattern 430 may vary based on an application or a design in accordance with one or more embodiments of the present invention. In other embodiments (not independently illustrated), second conductive pattern 430 may include any other pattern formed by a plurality of conductive lines or features in any shape or pattern. One of ordinary skill in the art will recognize that the composition of a conductive pattern may vary based on an application or design in accordance with one or more embodiments of the present invention.

In certain embodiments, the plurality of parallel conductive lines oriented in the first direction 510 may be perpendicular to the plurality of parallel conductive lines oriented in the second direction 520, thereby forming the mesh. In other embodiments, the plurality of parallel conductive lines oriented in the first direction 510 may be angled relative to the plurality of parallel conductive lines oriented in the second direction 520, thereby forming the mesh. One of ordinary skill in the art will recognize that the relative angle between the plurality of parallel conductive lines oriented in the first direction 510 and the plurality of parallel conductive lines oriented in the second direction 520 may vary based on an application or a design in accordance with one or more embodiments of the present invention. In other embodiments (not independently illustrated), a conductive pattern may include one or more conductive lines or features in any shape or pattern. One of ordinary skill in the art will also recognize that a conductive pattern is not limited to sets of parallel conductive lines and could be any other shape or pattern, including predetermined or random orientations of line segments, curved line segments, conductive particles, polygons, or any other shape(s) or pattern(s) comprised of electrically conductive material in accordance with one or more embodiments of the present invention.

In certain embodiments, a plurality of breaks 530 may partition second conductive pattern 430 into a plurality of row lines 320, each electrically partitioned from the others. Each row line 320 may route to a channel pad 540. Each channel pad 540 may route to an interface connector 560 by way of one or more interconnect conductive lines 550. Interface connectors 560 may provide a connection interface between the touch sensor (130 of FIG. 1) and the controller (210 of FIG. 2).

FIG. 7 shows a portion of a touch sensor 130 in accordance with one or more embodiments of the present invention. In certain embodiments, a touch sensor 130 may be formed, for example, by disposing a first conductive pattern 420 on a top, or user-facing, side of a transparent substrate (e.g., transparent substrate 410) and disposing a second conductive pattern 430 on a bottom side of the transparent substrate (e.g., transparent substrate 410). In other embodiments, a touch sensor 130 may be formed, for example, by disposing a first conductive pattern 420 on a side of a first transparent substrate (e.g., transparent substrate 410) and disposing a second conductive pattern 430 on a side of a second transparent substrate (e.g., transparent substrate 410). One of ordinary skill in the art will recognize that the disposition of the conductive pattern or patterns may vary based on the touch sensor 130 stackup in accordance with one or more embodiments of the present invention. In embodiments that use two conductive patterns, the first conductive pattern 420 and the second conductive pattern 430 may be horizontally and/or vertically offset relative to one another. The offset between the first conductive pattern 420 and the second conductive pattern 430 may vary based on an application or a design.

In certain embodiments, the first conductive pattern 420 may include a plurality of parallel conductive lines oriented in a first direction (510 of FIG. 5) and a plurality of parallel conductive lines oriented in a second direction (520 of FIG. 5) that form a mesh that is partitioned by a plurality of breaks (530 of FIG. 5) into electrically partitioned column lines 310. In certain embodiments, the second conductive pattern 430 may include a plurality of parallel conductive lines oriented in a first direction (510 of FIG. 6) and a plurality of parallel conductive lines oriented in a second direction (520 of FIG. 6) that form a mesh that is partitioned by a plurality of breaks (530 of FIG. 6) into electrically partitioned row lines 320. In operation, a controller (210 of FIG. 2) may electrically drive one or more row lines 320 (or column lines 310) and touch sensor 130 senses touch on one or more column lines 310 (or row lines 320) sampled by the controller (210 of FIG. 2). In other embodiments, the role of the first conductive pattern 420 and the second conductive pattern 430 may be reversed.

In certain embodiments, one or more of the plurality of parallel conductive lines oriented in a first direction (510 of FIG. 5 or FIG. 6), one or more of the plurality of parallel conductive lines oriented in a second direction (520 of FIG. 5 or FIG. 6), one or more of the plurality of breaks (530 of FIG. 5 or FIG. 6), one or more of the plurality of channel pads (540 of FIG. 5 or FIG. 6), one or more of the plurality of interconnect conductive lines (550 of FIG. 5 or FIG. 6), and/or one or more of the plurality of interface connectors (560 of FIG. 5 or FIG. 6) of the first conductive pattern 420 or second conductive pattern 430 may have different line widths and/or different orientations. In addition, the number of parallel conductive lines oriented in the first direction (510 of FIG. 5 or FIG. 6), the number of parallel conductive lines oriented in the second direction (520 of FIG. 5 or FIG. 6), and the line-to-line spacing between them may vary based on an application or a design. One of ordinary skill in the art will recognize that the size, configuration, and design of each conductive pattern may vary in accordance with one or more embodiments of the present invention.

In certain embodiments, one or more of the plurality of parallel conductive lines oriented in the first direction (510 of FIG. 5 or FIG. 6) and one or more of the plurality of parallel conductive lines oriented in the second direction (520 of FIG. 5 or FIG. 6) may have a line width less than approximately 5 micrometers. In other embodiments, one or more of the plurality of parallel conductive lines oriented in the first direction (510 of FIG. 5 or FIG. 6) and one or more of the plurality of parallel conductive lines oriented in the second direction (520 of FIG. 5 or FIG. 6) may have a line width in a range between approximately 5 micrometers and approximately 10 micrometers. In still other embodiments, one or more of the plurality of parallel conductive lines oriented in the first direction (510 of FIG. 5 or FIG. 6) and one or more of the plurality of parallel conductive lines oriented in the second direction (520 of FIG. 5 or FIG. 6) may have a line width in a range between approximately 10 micrometers and approximately 50 micrometers. In still other embodiments, one or more of the plurality of parallel conductive lines oriented in the first direction (510 of FIG. 5 or FIG. 6) and one or more of the plurality of parallel conductive lines oriented in the second direction (520 of FIG. 5 or FIG. 6) may have a line width greater than approximately 50 micrometers. One of ordinary skill in the art will recognize that the shape and width of one or more of the plurality of parallel conductive lines oriented in the first direction (510 of FIG. 5 or FIG. 6) and one or more of the plurality of parallel conductive lines oriented in the second direction (520 of FIG. 5 or FIG. 6) may vary in accordance with one or more embodiments of the present invention.

In certain embodiments, one or more of the plurality of channel pads (540 of FIG. 5 or FIG. 6), one or more of the plurality of interconnect conductive lines (550 of FIG. 5 or FIG. 6), and/or one or more of the plurality of interface connectors (560 of FIG. 5 or FIG. 6) may have a different width or orientation. In addition, the number of channel pads (540 of FIG. 5 or FIG. 6), interconnect conductive lines (550 of FIG. 5 or FIG. 6), and/or interface connectors (560 of FIG. 5 or FIG. 6) and the line-to-line spacing between them may vary based on an application or a design. One of ordinary skill in the art will recognize that the size, configuration, and design of each channel pad (540 of FIG. 5 or FIG. 6), interconnect conductive line (550 of FIG. 5 or FIG. 6), and/or interface connector (560 of FIG. 5 or FIG. 6) may vary in accordance with one or more embodiments of the present invention.

In typical applications, each of the one or more channel pads (540 of FIG. 5 and FIG. 6), interconnect conductive lines (550 of FIG. 5 and FIG. 6), and/or interface connectors (560 of FIG. 5 and FIG. 6) have a width substantially larger than each of the plurality of parallel conductive lines oriented in a first direction (510 of FIG. 5 or FIG. 6) or each of the plurality of parallel conductive lines oriented in a second direction (520 of FIG. 5 or FIG. 6). One of ordinary skill in the art will recognize that the size, configuration, and design as well as the number, shape, and width of channel pads (540 of FIG. 5 or FIG. 6), interconnect conductive lines (550 of FIG. 5 or FIG. 6), and/or interface connectors (560 of FIG. 5 or FIG. 6) may vary based on an application or a design in accordance with one or more embodiments of the present invention.

A conductive pattern (e.g., 420 or 430) may exhibit specular reflectance when viewed from certain angles, such as, for example, oblique angles. In certain designs or applications, this reflectance may be undesirable. For example, this reflectance may be undesirable when one or more conductive patterns are used as part of a touch sensor (130 of FIG. 1) that overlays or is integrated into a display device (110 of FIG. 1). However, this reflectance is typically only visible when the display device (110 of FIG. 1) is not emitting light or is otherwise turned off. When the display device (110 of FIG. 1) is operational and emitting light, the specular reflectance from the conductive pattern or patterns is substantially lower in magnitude compared to the light emitted from the display device (110 of FIG. 1) such that it is not discernible to a human viewer.

In one or more embodiments of the present invention, a watermarked conductive pattern adds filler shapes between the individual conductive lines or features (e.g., 510 and 520) of a conductive pattern (e.g., 420 or 430), typically located on the side of the touch sensor (130 of FIG. 4) nearest the user in the touch sensor or display device (not shown) stack. This position in the stack maximizes the reflected effect of the filler shapes. The viewable area of the conductive pattern adjacent to a predetermined watermark area (not shown), may be filled with a plurality of background filler shapes (not shown) that do not contact or otherwise affect the electrical performance of the conductive lines or features (e.g., 510 and 520) that form the conductive pattern. A watermark, graphic, image, or logo, hereinafter referred to individually or collectively as a watermark, may be formed by filling the predetermined watermark area (anywhere in viewable area of conductive pattern) with a plurality of watermark filler shapes (not shown) that do not contact or otherwise affect the electrical performance of the conductive lines (e.g., 510 and 520) that form the conductive pattern. The background filler shapes (not shown) and the watermark filler shapes (not shown) may reflect or refract light differently, thus providing a contrast between the watermark area and the remaining viewable area of the conductive pattern at certain angles when the display device (110 of FIG. 1) is not emitting light. In other embodiments, a watermarked conductive pattern may be used in non-touch sensor applications to provide a decorative effect in accordance with one or more embodiments of the present invention.

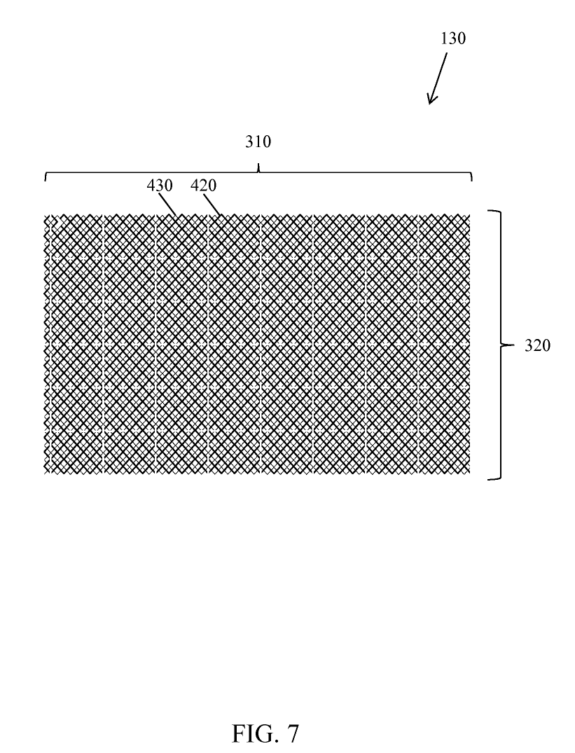

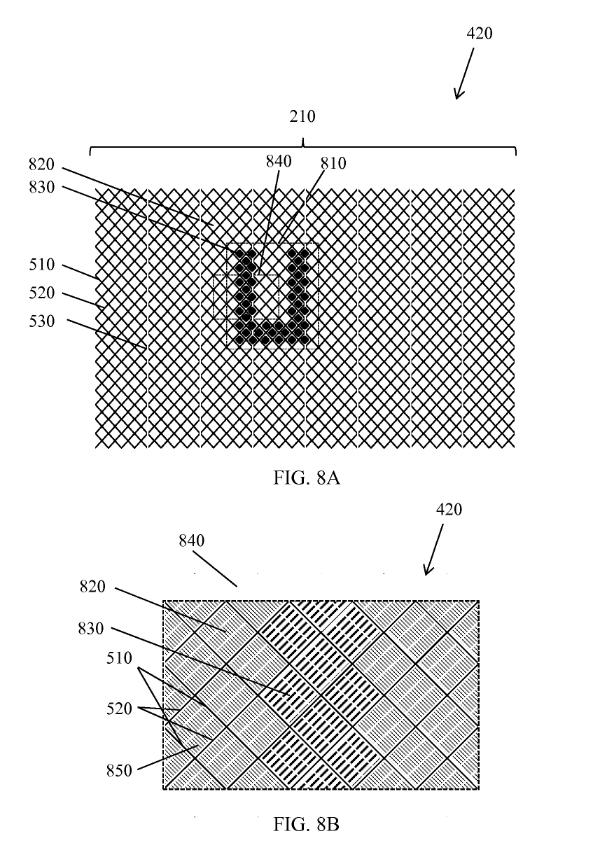

FIG. 8A shows a portion of a watermarked conductive pattern 420 in accordance with one or more embodiments of the present invention. In certain embodiments, a watermark 810 may be formed in one or more conductive patterns (e.g., 420 or 430 of FIG. 4) of a touch sensor (130 of FIG. 4). While FIG. 8A and the discussion that follows discusses the use of conductive pattern 420 as the watermarked conductive pattern, one of ordinary skill in the art will recognize that conductive pattern 430 could be watermarked in a similar manner. In other embodiments, watermark 810 may be formed in any other conductive pattern in the touch sensor (130 of FIG. 4) or display device (not shown) stack. In still other embodiments, watermark 810 may be formed by a pattern (not shown) that provides a decorative effect as an overlay or that is integrated into a display device (not shown) stack. One of ordinary skill in the art will recognize that while the discussion that follows discusses the use of conductive pattern 420, the same technique may be applied to any conductive pattern in accordance with one or more embodiments of the present invention.

In certain embodiments, watermark 810 may be formed in, for example, conductive pattern 420 by forming a plurality of watermark filler shapes 830 in a predetermined watermark area. The watermark filler shapes 830 do not contact or otherwise affect the electrical performance of the conductive lines (510 and 520 of FIG. 5) that form conductive pattern 420. A plurality of background filler shapes 820 are formed in a viewable area of the conductive pattern 420 adjacent to the predetermined watermark area. The background filler shapes 820 also do not contact or otherwise affect the electrical performance of the conductive lines (510 and 520 of FIG. 5) that form conductive pattern 420. Background filler shapes 820 and watermark filler shapes 830 may exhibit different reflection and/or refraction characteristics that affect the reflection or propagation of light based on differences in one or more of the ink composition, material composition, metal, color, size, shape, pattern, or orientation, or refractive index of the filler shapes used. As a consequence, at certain angles, background filler shapes 820 may reflect and/or refract light more than watermark filler shapes 830 and at other angles watermark filler shapes 830 may reflect and/or refract light more than background filler shapes 820. In each circumstance, the contrast between the two makes watermark 810 discernible to a user-facing the display device at certain angles when the display device is not emitting light.

In certain embodiments that utilize ink, such as, for example, flexographic printing processes, clear or translucent ink may be used to print one or more of background filler shapes 820 and watermark filler shapes 830. Translucent ink may include microparticles or nanoparticles that have different refractive indices, patterns, or filler. The refractive index of background filler shapes 820 and watermark filler shapes 830 may be controlled by the type and composition of clear ink or translucent ink used, other ink composition, material composition, metal, color, size, shape, pattern, or orientation of the shapes such that background filler shapes 820 exhibit a different refractive index than watermark filler shapes 830.

In one or more embodiments of the present invention, background filler shapes 820 and watermark filler shapes 830 may be formed using the same process and the same materials used to form the one or more conductive patterns (e.g., 420 or 430 of FIG. 4). In other embodiments, background filler shapes 820 and watermark filler shapes 830 may be formed using different materials than the one or more conductive patterns including, but not limited to, embodiments that use non-conductive materials. In still other embodiments, background filler shapes 820 and watermark filler shapes 830 may be formed using any suitable material for providing the decorative watermark effect including, but not limited to, embodiments that use non-conductive materials, on a watermarked layer. One of ordinary skill in the art will recognize that any process suitable for forming a conductive pattern on substrate may be used to form background filler shapes and watermark filler shapes in the conductive pattern or on a transparent substrate in accordance with one or more embodiments of the present invention.

FIG. 8B shows a zoomed in view of a portion 840 of the watermarked conductive pattern 420 in accordance with one or more embodiments of the present invention. Within conductive pattern 420, the intersections of adjacent parallel conductive lines oriented in the first direction 510 and adjacent parallel conductive lines oriented in the second direction 520 forms a plurality of cells 850. In this way, each cell 850 is the area bounded by a pair of adjacent parallel conductive lines oriented in the first direction 510 and a pair of adjacent parallel conductive lines oriented in the second direction 520. Outside the predetermined watermark area, within cells 850, a plurality of background filler shapes 820 may be formed that do not contact or otherwise affect the electrical performance of the conductive lines (510 and 520) that form conductive pattern 420. Inside the predetermined watermark area, within cells 850, a plurality of watermark filler shapes 830 may be formed that do not contact or otherwise affect the electrical performance of the conductive lines (510 and 520) that form conductive pattern 420. Background filler shapes 820 and watermark filler shapes 830 exhibit different reflection and/or refraction characteristics that affect the reflection or propagation of light based on differences in one or more of the ink composition, material composition, metal, color, size, shape, pattern, or orientation of the shapes, or refractive indices of the shapes. In the example depicted in the figure, background filler shapes 820 differ from watermark filler shapes 830 in size and orientation. One of ordinary skill in the art will recognize background filler shapes 820 and watermark filler shapes 830 may vary in one or more ink composition, material composition, metal, color, size, shape, pattern, or orientation, or refractive indices of the shapes in accordance with one or more embodiments of the present invention.

As a consequence, at certain angles, background filler shapes 820 may reflect and/or refract light more than watermark filler shapes 830 and at other angles watermark filler shapes 830 may reflect and/or refract light more than background filler shapes 820. In each circumstance, the contrast between the two makes watermark 810 discernible to a user-facing the display device at certain angles when the display device is not emitting light. In FIG. 8B, background filler shapes 820 and watermark filler shapes 830 are composed of rectangular line segments that are oriented in different directions that cause them to reflect and/or refract light differently. However, one of ordinary skill in the art will recognize that background filler shapes 820 and watermark filler shapes 830 may vary in one or more of ink composition, material composition, metal, color, size, shape, pattern, or orientation, or refractive indices in accordance with one or more embodiments of the present invention.

In one or more embodiments of the present invention, variations of the techniques discussed herein may be used to achieve a desired decorative effect for applications or designs that do not require a touch sensor. In certain embodiments, a watermarked display device may include a display device (110 of FIG. 1) and a watermarked layer (not shown) that overlays or that is integrated into the display device (110 of FIG. 1). The watermarked layer (not shown) may include a transparent substrate (410 of FIG. 4), a plurality of watermark filler shapes (830 of FIG. 8) disposed on the transparent substrate (410 of FIG. 4) in a predetermined watermark area, and a plurality of background filler shapes (820 of FIG. 8) disposed on the transparent substrate (410 of FIG. 4) in an area adjacent to the predetermined watermark area. In such an embodiment, the conductive pattern formed by the watermark filler shapes and the background filler shapes may not provide a touch sensor function, but merely a decorative watermark effect. One of ordinary skill in the art will recognize that the watermarked display device may vary based on techniques discussed herein in accordance with one or more embodiments of the present invention.

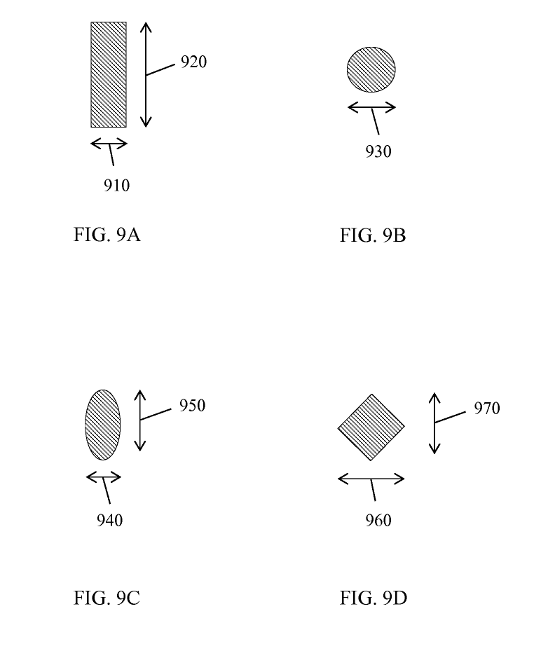

FIGS. 9A through 9D show different filler shapes in accordance with one or more embodiments of the present invention. In FIG. 9A, a rectangular filler shape is depicted. The rectangular filler shape may have a width 910 and a length 920 that may vary based on an application or a design. In certain embodiments, the width 910 of the rectangular filler shape may be the same as the width of one or more conductive lines (510 or 520 of FIG. 8). In other embodiments, the width 910 of the rectangular filler shape may be smaller than the width of one or more conductive lines (510 or 520 of FIG. 8). In still other embodiments, the width 910 of the rectangular filler shape may be larger than the width of one or more conductive lines (510 or 520 of FIG. 8). One of ordinary skill in the art will recognize that the width 910 of the rectangular filler shape may vary based on an application or a design in accordance with one or more embodiments of the present invention. One of ordinary skill in the art will also recognize that the length 920 of the rectangular filler shape may vary based on an application or a design in accordance with one or more embodiments of the present invention.

In FIG. 9B, a circular filler shape is depicted. The circular filler shape may have a diameter 930 that may vary based on an application or a design. In certain embodiments, the diameter 930 of the circular filler shape may be the same as the width of one or more conductive lines (510 or 520 of FIG. 8). In other embodiments, the diameter 930 of the circular filler shape may be smaller than the width of one or more conductive lines (510 or 520 of FIG. 8). In still other embodiments, the diameter 930 of the circular filler shape may be larger than the width of one or more conductive lines (510 or 520 of FIG. 8). One of ordinary skill in the art will recognize that the diameter 930 of the circular filler shape may vary based on an application or a design in accordance with one or more embodiments of the present invention.

In FIG. 9C, an oval filler shape is depicted. The oval filler shape may have a minor diameter 940 and a major diameter 950 that may vary based on an application or a design. In certain embodiments, the minor diameter 940 of the oval filler shape may be the same as the width of one or more conductive lines (510 or 520 of FIG. 8). In other embodiments, the minor diameter 940 of the oval filler shape may be smaller than the width of one or more conductive lines (510 or 520 of FIG. 8). In still other embodiments, the minor diameter 940 of the oval filler shape may be larger than the width of one or more conductive lines (510 or 520 of FIG. 8). One of ordinary skill in the art will recognize that the minor diameter 940 of the oval filler shape may vary based on an application or a design in accordance with one or more embodiments of the present invention. One of ordinary skill in the art will also recognize that the major diameter 950 of the oval filler shape may vary based on an application or a design in accordance with one or more embodiments of the present invention.

In FIG. 9D, a square filler shape is depicted. The square filler shape may have a width 960 and a length 970 that may vary based on an application or a design. In certain embodiments, the width 960 of the square support structure may be the same as the width of one or more conductive lines (510 or 520 of FIG. 8). In other embodiments, the width 960 of the square filler shape may be smaller than the width of one or more conductive lines (510 or 520 of FIG. 8). In other embodiments, the width 960 of the square filler shape may be larger than the width of one or more conductive lines (510 or 520 of FIG. 8). One of ordinary skill in the art will recognize that the width 960 of the square filler shape may vary based on an application or a design in accordance with one or more embodiments of the present invention. One of ordinary skill in the art will also recognize that the length 970 of the square filler shape may vary based on an application or a design in accordance with one or more embodiments of the present invention.

While FIGS. 9A through 9D depict a number of filler shapes, one of ordinary skill in the art will recognize that any other filler shape or shapes may be used in accordance with one or more embodiments of the present invention. In addition, one of ordinary skill in the art will recognize that the number of filler shapes placed within a cell (850 of FIG. 8) as well as the ink composition, material composition, metal, color, size, shape, pattern, or orientation, or refractive index of the filler shapes may vary in accordance with one or more embodiments of the present invention. One of ordinary skill in the art will also recognize that there may be more than one watermark area and each area may utilize different filler shapes to vary the decorative effect in accordance with one or more embodiments of the present invention.

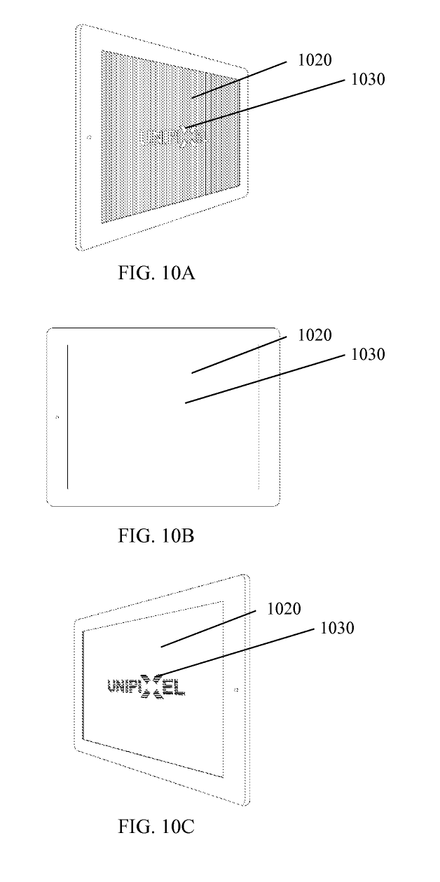

FIG. 10A shows a left perspective view of a tablet with a watermarked conductive pattern or watermarked display device in accordance with one or more embodiments of the present invention. In order to achieve the desired visual effect, the background filler shapes and watermark filler shapes selected will necessarily be different in one or more property, such as ink composition, material composition, metal, color, size, shape, pattern, or orientation, or refractive index. Because background filler shapes 1020 reflect and/or refract light differently than watermark filler shapes 1030, the watermark is discernible to an end-user facing the tablet from a left perspective when the tablet is not emitting light or is otherwise turned off. As previously discussed, the ability to discern the watermark is based on the contrast between the way background filler shapes 1020 reflect and/or refract light when compared to the way the watermark filler shapes 1030 reflect and/or refract light. In this example, when viewing from a left perspective, when the tablet is not emitting light or otherwise turned off, background filler shapes 1020 appear darker when compared to watermark filler shapes 1030. One of ordinary skill in the art will recognize that the filler shapes could be reversed such that background filler shapes 1020 appear lighter when compared to watermark filler shapes 1030 when the tablet is not emitting light or otherwise turned off

FIG. 10B shows a user-facing perspective view of the tablet with the watermarked conductive pattern or watermarked display device in accordance with one or more embodiments of the present invention. When viewed from the user-facing perspective, the conductive pattern (not shown), if any, exhibits little to no specular reflectance. As a consequence, the conductive pattern (not shown), background filler shapes (1020 of FIG. 10A), and watermark filler shapes (1030 of FIG. 10B) may not be visible to a user facing the tablet at a normal operating distance from the tablet.

FIG. 10C shows a right perspective view of the tablet with the watermarked conductive pattern or watermarked display device in accordance with one or more embodiments of the present invention. Because background filler shapes 1020 reflect and/or refract light differently than watermark filler shapes 1030, the watermark is discernible to an end-user facing the tablet from a right perspective when the tablet is not emitting light or is otherwise turned off. As previously discussed, the ability to discern the watermark is based on the contrast between the way background filler shapes 1020 reflect and/or refract light when compared to the way the watermark filler shapes 1030 reflect and/or refract light. In this example, when viewing from a right perspective, when the tablet is not emitting light or otherwise turned off, background filler shapes 1020 appear lighter when compared to watermark filler shapes 1030. One of ordinary skill in the art will recognize that the filler shapes could be reversed such that background filler shapes 1020 appear darker when compared to watermark filler shapes 1030 when the tablet is not emitting light or otherwise turned off. One of ordinary skill in the art will also recognize that the contrast between the reflection and/or refraction of light from the background filler shapes and the watermark filler shapes is not limited to just left versus right views. Any viewable perspective of the display device will exhibit the watermark visual effect when viewed at a similar oblique angle with respect to the surface of the display.

FIG. 11A shows a left perspective view of a smartphone with a watermarked conductive pattern or watermarked display device in accordance with one or more embodiments of the present invention. FIG. 11B shows a user-facing perspective view of the smartphone with the watermarked conductive pattern or watermarked display device in accordance with one or more embodiments of the present invention. FIG. 11C shows a right perspective view of the smartphone with the watermarked conductive pattern or watermarked display device in accordance with one or more embodiments of the present invention.

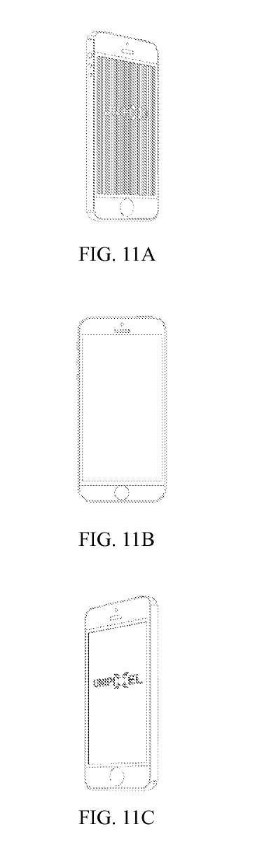

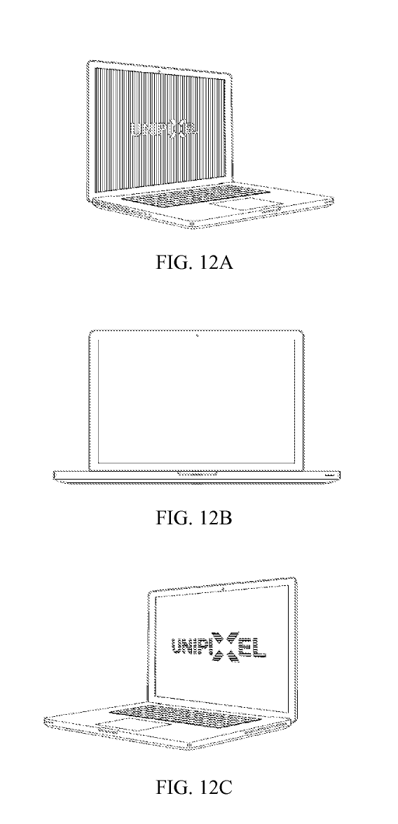

FIG. 12A shows a left perspective view of a laptop with a watermarked conductive pattern or watermarked display device in accordance with one or more embodiments of the present invention. FIG. 12B shows a user-facing perspective view of the laptop with the watermarked conductive pattern or watermarked display device in accordance with one or more embodiments of the present invention. FIG. 12C shows a right perspective view of the laptop with the watermarked conductive pattern or watermarked display device in accordance with one or more embodiments of the present invention.

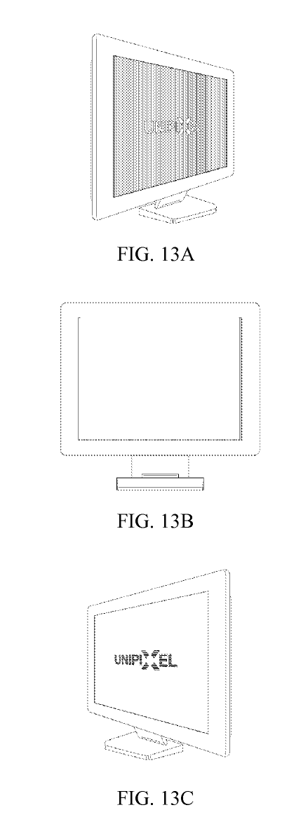

FIG. 13A shows a left perspective view of a monitor with a watermarked conductive pattern or watermarked display device in accordance with one or more embodiments of the present invention. FIG. 13B shows a user-facing perspective view of the monitor with the watermarked conductive pattern or watermarked display device in accordance with one or more embodiments of the present invention. FIG. 13C shows a right perspective view of the monitor with the watermarked conductive pattern or watermarked display device in accordance with one or more embodiments of the present invention.

Advantages of one or more embodiments of the present invention may include one or more of the following:

In one or more embodiments of the present invention, a watermarked conductive pattern provides for different optical effects on different areas of a conductive pattern such that a desirable pattern is visible to an end user at certain angles when an underlying display device is not emitting light or is otherwise turned off.

In one or more embodiments of the present invention, a watermarked conductive pattern uses the specular reflectance of watermark filler shapes and background filler shapes to provide a decorative effect, such as a watermark or logo, when viewed at certain angles and an underlying display device is not emitting light or is otherwise turned off. When the underlying display device is emitting light, the watermark filler shapes and the background filler shapes are not visible to an end user under normal operating conditions.

In one or more embodiments of the present invention, a watermarked conductive pattern includes a plurality of watermark filler shapes in one or more predetermined watermark or logo areas and background filler shapes in the area adjacent to the predetermined watermark or logo areas. The watermark filler shapes reflect or refract light differently than the background filler shapes. The contrast between the watermark filler shapes and the background filler shapes is discernible to an end user at certain angles when the underlying display device is not emitting light or is otherwise turned off. The contrast may be controlled by varying one or more of the ink composition, material composition, metal, color, size, shape, pattern, or orientation, or refractive index of the watermark filler shapes as compared to the background filler shapes.

In one or more embodiments of the present invention, a watermarked conductive pattern includes watermark filler shapes that differ from the background filler shapes in one or more of size, shape, pattern, or orientation, or refractive indices.

In one or more embodiments of the present invention, a watermarked conductive pattern provides watermark filler shapes and background filler shapes disposed in a plurality of cells formed between a plurality of parallel conductive lines oriented in a first direction and a plurality of parallel conductive lines oriented in a second direction of the user-facing conductive pattern.

In one or more embodiments of the present invention, a watermarked conductive pattern provides watermark filler shapes and background filler shapes that are electrically isolated from the plurality of parallel conductive lines oriented in a first direction and the plurality of parallel conductive lines oriented in a second direction of the user-facing conductive pattern

In one or more embodiments of the present invention, a watermarked conductive pattern may be formed using the same process used to form the conductive pattern or patterns.

In one or more embodiments of the present invention, a watermarked conductive pattern is compatible with flexographic printing processes.

In one or more embodiments of the present invention, a watermarked conductive pattern is compatible with other conductive pattern fabrication processes.

In one or more embodiments of the present invention, a watermarked conductive pattern uses translucent ink with microparticles or nanoparticles that have a different refractive indices, patterns, or filler material.

While the present invention has been described with respect to the above-noted embodiments, those skilled in the art, having the benefit of this disclosure, will recognize that other embodiments may be devised that are within the scope of the invention as disclosed herein. Accordingly, the scope of the invention should be limited only by the appended claims.

What is claimed is:

1. A watermarked conductive pattern comprising:
a conductive pattern disposed on a transparent substrate;
a plurality of watermark filler shapes disposed on the transparent substrate in a predetermined watermark area; and
a plurality of background filler shapes disposed on the transparent substrate in an area adjacent to the predetermined watermark area.

2. The watermarked conductive pattern of claim 1, wherein the conductive pattern comprises an electroless plated metal.

3. The watermarked conductive pattern of claim 1, wherein the conductive pattern comprises a transparent conductor.

4. The watermarked conductive pattern of claim 1, wherein the conductive pattern comprises indium tin oxide.

5. The watermarked conductive pattern of claim 1, wherein the conductive pattern comprises Poly(3,4-ethylenedioxythiophene).

6. The watermarked conductive pattern of claim 1, wherein the conductive pattern comprises a plurality of parallel conductive lines oriented in a first direction and a plurality of parallel conductive lines oriented in a second direction.

7. The watermarked conductive pattern of claim 6, wherein the plurality of watermark filler shapes and the plurality of background filler shapes are disposed in a plurality of cells formed between the plurality of parallel conductive lines oriented in the first direction and the plurality of parallel conductive lines oriented in the second direction.

8. The watermarked conductive pattern of claim 6, wherein the plurality of watermark filler shapes and the plurality of background filler shapes are electrically isolated from the plurality of parallel conductive lines oriented in a first direction and the plurality of parallel conductive lines oriented in a second direction.

9. The watermarked conductive pattern of claim 1, wherein the plurality of watermark filler shapes differ from the plurality of background filler shapes in one or more of size or shape.

10. The watermarked conductive pattern of claim 1, wherein the plurality of watermark filler shapes are comprised of a different material than the plurality of background filler shapes.

11. The watermarked conductive pattern of claim 1, wherein the plurality of watermark filler shapes differ from the plurality of background filler shapes in pattern.

12. The watermarked conductive pattern of claim 1, wherein the plurality of watermark filler shapes differ from the plurality of background filler shapes in orientation.

13. The watermarked conductive pattern of claim 1, wherein the plurality of watermark filler shapes differ from the plurality of background filler shapes in refractive index.

14. The watermarked conductive pattern of claim 1, wherein the plurality of watermark filler shapes reflect or refract light differently than the plurality of background filler shapes.

15. The watermarked conductive pattern of claim 1, wherein the plurality of watermark filler shapes form a watermark viewable to an end user when a display device is not emitting light.

16. A watermarked display device comprising:
a display device; and
a transparent substrate,
wherein a plurality of watermark filler shapes are disposed on the transparent substrate in a predetermined watermark area, and
wherein a plurality of background filler shapes are disposed on the transparent substrate in an area adjacent to the predetermined watermark area.

17. The watermarked display device of claim 16, further comprising a conductive pattern.

18. The watermarked display device of claim 17, wherein the conductive pattern comprises a plurality of parallel conductive lines oriented in a first direction and a plurality of parallel conductive lines oriented in a second direction.

19. The watermarked display device of claim 18, wherein the plurality of watermark filler shapes and the plurality of background filler shapes are disposed in a plurality of cells formed between the plurality of parallel conductive lines oriented in the first direction and the plurality of parallel conductive lines oriented in the second direction.

20. The watermarked display device of claim 18, wherein the plurality of watermark filler shapes and the plurality of background filler shapes are electrically isolated from the plurality of parallel conductive lines oriented in a first direction and the plurality of parallel conductive lines oriented in a second direction.

21. The watermarked display device of claim 17, wherein the conductive pattern comprises an electroless plated metal.

22. The watermarked display device of claim 17, wherein the conductive pattern comprises a transparent conductor.

23. The watermarked display device of claim 17, wherein the conductive pattern comprises indium tin oxide.

24. The watermarked display device of claim 17, wherein the conductive pattern comprises Poly(3,4-ethylenedioxythiophene).

25. The watermarked display device of claim 16, wherein the transparent substrate is disposed over the display device.

26. The watermarked display device of claim 16, wherein the transparent substrate is integrated into the display device.

27. The watermarked display device of claim 16, wherein the plurality of watermark filler shapes differ from the plurality of background filler shapes in one or more of size or shape.

28. The watermarked display device of claim 16, wherein the plurality of watermark filler shapes are comprised of a different material than the plurality of background filler shapes.

29. The watermarked display device of claim 16, wherein the plurality of watermark filler shapes differ from the plurality of background filler shapes in pattern.

30. The watermarked display device of claim 16, wherein the plurality of watermark filler shapes differ from the plurality of background filler shapes in orientation.

31. The watermarked display device of claim 16, wherein the plurality of watermark filler shapes differ from the plurality of background filler shapes in refractive indices.

32. The watermarked display device of claim 16, wherein the plurality of watermark filler shapes reflect or refract light differently than the plurality of background filler shapes.

33. The watermarked display device of claim 16, wherein the plurality of watermark filler shapes form a watermark viewable to an end user when a display device is not emitting light.
